(19) United States
(12) Patent Application Publication
(10) Pub. No.: US 2012/0256163 A1
(43) Pub. Date: Oct. 11, 2012

(54) LIGHT EMITTING UNIT AND DISPLAY DEVICE INCLUDING THE SAME

(76) Inventors: Sanghyuck YOON, Seoul (KR); Chan-Jae Park, Suyeong-gu (KR)

(21) Appl. No.: 13/443,732

(22) Filed: Apr. 10, 2012

(30) Foreign Application Priority Data
Apr. 11, 2011 (KR) 10-2011-0033482

(51) Int. Cl. H01L 33/06

(52) U.S. Cl. 257/13; 257/E33.008

(57) ABSTRACT

A display device including a display panel and a light emitting unit providing light to the display panel is described herein. The light emitting unit includes a light emitting diode and a light emitting layer. The light emitting diode emits a first light. The light emitting layer includes quantum dots and fluorescent particles. The quantum dots are disposed on the light emitting diode and absorb the first light to emit a second light of a wavelength different from that of the first light. The fluorescent particles absorb the first light to emit a third light of a wave length different from those of the first and second light.

### CROSS-REFERENCE TO RELATED APPLICATIONS

This U.S. non-provisional patent application claims priority under 35 U.S.C. §119 of Korean Patent Application No. 10-2011-0033482, filed on Apr. 11, 2011, the entire contents of which are hereby incorporated by reference.

### BACKGROUND

The present disclosure relates to a light emitting unit and a display device including the light emitting unit.

Liquid crystal display devices include a display panel for displaying an image. Since the display panel is a non-emissive panel, the display panel requires a separate light source. Thus, a liquid crystal display device includes a display panel and a light emitting unit providing light to the display panel.

In general, a light emitting unit includes a blue light emitting diode and a fluorescent material. In addition, the light emitting diode has a PN junction with electrodes and a semiconductor. Electrons and holes in the semiconductor are recombined across a band gap at a PN junction from the electrodes. When the electrons and the holes are recombined energy corresponding to the band gap is emitted as light. The fluorescent particles absorb a portion of light emitted from the light emitting diode and are excited to emit green or blue light. As such the light emitting unit emits white light.

### SUMMARY

The present disclosure provides a light emitting unit having excellent color reproducibility.

The present disclosure also provides a display device having excellent color reproducibility and high brightness.

Embodiments of the inventive concept provide light emitting units including a light emitting diode and a light emitting layer.

The light emitting diode emits first light. The light emitting layer includes quantum dots and fluorescent particles. The quantum dots are disposed on the light emitting diode and absorb the first light to emit a second light having a wavelength different from that of the first light. The fluorescent particles absorb the first light to emit a third light having a wave length different from those of the first and second light.

In some embodiments, the first light may have a peak wavelength ranging from about 380 nm to about 470 nm. The second light may have a peak wavelength ranging from about 500 nm to about 560 nm, and the third light may have a peak wavelength ranging from about 580 nm to about 650 nm.

In other embodiments, the fluorescent particles may be nitride-based fluorescent particles, and include at least one of CaAlSiN₃:Eu and SrAlSiN₃:Eu.

In still other embodiments, the quantum dots may include at least one of ZnSe, CdSe, and InGaP.

In other embodiments of the inventive concept, display devices include a display panel displaying an image, and the light emitting unit providing light to the display panel.

In some embodiments, the display panel may include: a first substrate; a second substrate opposed to the first substrate; an image display layer disposed between the first and second substrates; and a color filter layer disposed between the first substrate and the image display layer or between the second substrate and the image display layer to express a color.

In other embodiments, the color filter layer may include: a first color filter for transmitting light of a first wavelength band; a second color filter for transmitting light of a second wavelength band that is different from the first wavelength band; and a third color filter for transmitting light of a third wavelength band that is different from the first and second wavelength bands, wherein the first wavelength band ranges from about 380 nm to about 550 nm, the second wavelength band ranges from about 450 nm to about 655 nm, and the third wavelength band ranges from about 540 nm to about 780 nm.

### BRIEF DESCRIPTION OF THE DRAWINGS

The accompanying figures are included to provide a further understanding of the inventive concept, and are incorporated in and constitute a part of this specification. The drawings illustrate exemplary embodiments of the inventive concept and, together with the description, serve to explain principles of the inventive concept. In the figures:

FIG. 1 is an exploded perspective view illustrating a display device according to an embodiment of the inventive concept;

FIG. 2 is a partial cut-away perspective view illustrating a portion of a display panel according to one embodiment;

FIG. 3 is a cross-sectional view illustrating a light emitting unit according to an embodiment of the inventive concept;

FIG. 4A is a spectral energy distribution graph of a typical light emitting unit;

FIG. 4B is a spectral energy distribution graph of a light emitting unit according to an embodiment of the inventive concept;

FIG. 5A is a diagram of color coordinates (x, y) illustrating a color reproduction region of a light emitting unit in a CIE 1931 standard colorimetric system according to an embodiment of the inventive concept;

FIG. 5B is an enlarged view illustrating a portion RR of a green region of FIG. 5A;

FIG. 6 is a graph illustrating transmissivity of color filters according to wavelengths, according to an embodiment of the inventive concept;

FIG. 7A is a spectral energy distribution graph of a typical light emitting unit according to an experimental example;

FIG. 7B is a graph illustrating transmissivity of typical color filters according to wavelengths, according to the experimental example of FIG. 7A;

FIG. 7C is a diagram of color coordinates (x, y) illustrating a color reproduction region of a display device including the light emitting unit of FIG. 7A and the color filters of FIG. 7B, in the CIE 1931 standard colorimetric system;

FIG. 8A is a spectral energy distribution graph of a light emitting unit according to another experimental example;

FIG. 8B is a graph illustrating transmissivity of typical color filters in the experimental example of FIG. 8A;

FIG. 8C is a diagram of color coordinates (x, y) illustrating a color reproduction region of a display device including the light emitting unit of FIG. 8A and the color filters of FIG. 8B, in the CIE 1931 standard colorimetric system;

FIG. 9A is a spectral energy distribution graph of a light emitting unit according to an embodiment of the inventive concept;

FIG. 9B is a graph illustrating transmissivity of color filters according to wavelengths, according to the embodiment of FIG. 9A; and

FIG. 9C is a diagram of color coordinates (x, y) illustrating a color reproduction region of a display device including the light emitting unit of FIG. 9A and the color filters of FIG. 9B, in the CIE 1931 standard colorimetric system;

### DETAILED DESCRIPTION

Since the inventive concept may have diverse modified embodiments, embodiments are illustrated in the drawings and are described in the detailed description of the inventive concept. However, this does not limit the inventive concept within specific embodiments and it should be understood that the inventive concept covers all the modifications, equivalents, and replacements within the idea and technical scope of the inventive concept.

Like reference numerals refer to like elements throughout. In the drawings, the dimensions and size of each structure are exaggerated, omitted, or schematically illustrated for convenience in description and clarity. It will be understood that although the terms of first and second are used herein to describe various elements, these elements should not be limited by these terms. Terms are only used to distinguish one component from other components. Therefore, a component referred to as a first component in one embodiment can be referred to as a second component in another embodiment. The terms of a singular form may include plural forms unless referred to the contrary.

The meaning of ‘comprise’, ‘include’, or ‘have’ specifies a property, a region, a fixed number, a step, a process, an element and/or a component but does not exclude other properties, regions, fixed numbers, steps, processes, elements and/or components. In the specification, it will be understood that when a layer (or film), a region, or a plate is referred to as being ‘on’ another layer, region, or plate, it can be directly on the other layer, region, or plate, or intervening layers, regions, or plates may also be present. In the specification, it will be understood that when a layer (or film), a region, or a plate is referred to as being ‘under’ another layer, region, or plate, it can be directly under the other layer, region, or plate, or intervening layers, regions, or plates may also be present.

A light emitting unit and a display device including the light emitting unit as a light source will be sequentially described according to the inventive concept.

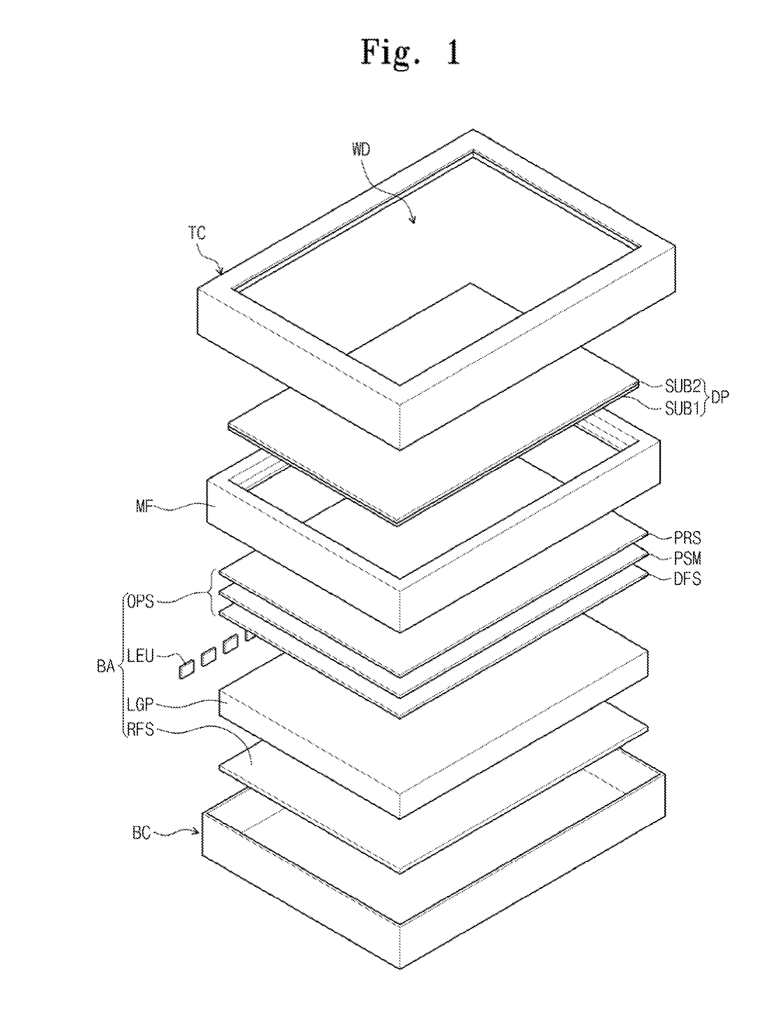

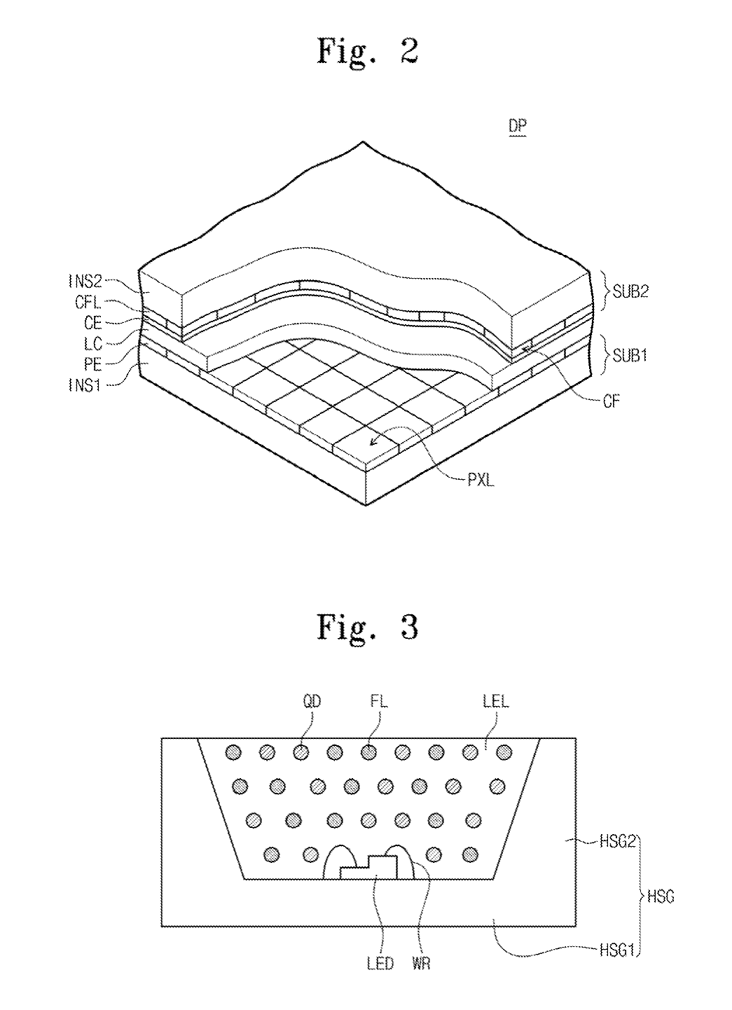

FIG. 1 is an exploded perspective view illustrating a display device according to the inventive concept. FIG. 2 is a partial cut-away perspective view illustrating a portion of a display panel according to the inventive concept.

The display device includes a display panel DP, a mold frame MF, a backlight assembly BA, a bottom chassis BC, and a top chassis TC.

The display panel DP displays an image. The display panel DP is a non-emissive display panel, which is one of various display panels such as a liquid crystal display panel, an electrophoretic display panel, an electrowetting display panel, and a microelectromechanical system (MEMS) display panel. In the current embodiment, a liquid crystal display panel is exemplified as the display panel DP.

Referring to FIG. 2, the display panel DP has a rectangular plate shape with short and long sides. The display panel DP includes a first substrate SUB1, a second substrate SUB2 opposed to the first substrate SUB1, and a liquid crystal layer LC disposed between the first and second substrates SUB1 and SUB2 and formed of liquid crystal molecules.

The first substrate SUB1 includes a first insulating substrate INS1 and a plurality of pixels PXL disposed on the first insulating substrate INS1. The pixels PXL may include pixel electrodes PE and thin film transistors (not shown) that correspond to the pixel electrodes PE and that are electrically connected thereto. Each thin film transistor is configured to switch a driving signal that is provided to the corresponding pixel electrode PE.

The second substrate SUB2 includes: a second insulating substrate INK opposed to the first insulating substrate INS1; a color filter layer CFL disposed on the second insulating substrate INS2 to express colors; and a common electrode CE disposed on the color filter layer CFL to form an electric field with the pixel electrodes PE. The color filter layer CFL provided on the second substrate SUB2 is disposed between the second insulating substrate INS2 and the common electrode CE. However, the position of the color filter layer CFL is not limited thereto, and thus, the color filter layer CFL may be disposed on the first substrate SUB1, particularly, between the first insulating substrate INS1 and the pixel electrodes PE.

The color filter layer CFL may include a plurality of color filters CF that are in one-to-one correspondence with the pixels PXL. The color filters CF may be different from one another to transmitting light of different wavelengths such that the pixels PXL express colors. For example, the color filters CF may include color filters for expressing red, green, and blue, or color filters for expressing red, green, blue, and white.

In the one embodiment, the color filter layer CFL includes first to third color filters for expressing three different colors.

The first color filter transmits light of a first wavelength band. The second color filter transmits light of a second wavelength band that is different from the first wavelength band. The third color filter transmits light of a third wavelength band that is different from the first and second wavelength bands. The first to third color filters express one of blue, green, and red according to the first to third wavelength bands. When the first to third color filters express blue, green, and red, respectively, the first wavelength band may range from about 380 nm to about 550 nm. In this case, the second wavelength band may range from about 450 nm to about 655 nm, and the third wave length band may range from about 540 nm to about 780 nm. The ranges of the first to third wavelength bands are given by expressing a region corresponding to a transmissivity of about 95%, as a boundary value.

The liquid crystal molecules are driven by an electric field formed by the pixel electrodes PE and the common electrode CE, and thus, the amount of light passing through the liquid crystal layer LC is adjusted to display an image.

The mold frame MF extends along the edge of the display panel DP, and supports the display panel DP. The mold frame MF has an approximately tetragonal ring shape. The mold frame MF may be provided as a single body as illustrated in FIG. 1, but may be provided as an assembly including a plurality of parts.

The backlight assembly BA provides light to the display panel DP, and is disposed under the display panel DP. The backlight assembly BA includes: at least one light emitting unit LEU for emitting light; a light guide plate LGP guiding the light to the display panel DP; optical sheets OPS for improving efficiency of the light; and a reflective sheet RFS changing a travelling direction of the light.

The light emitting unit LEU provides light to the light guide plate LGP. The light emitting unit LEU will be described later.

The light guide plate LGP has a rectangular parallelepiped plate shape and is disposed under the display panel DP. The light guide plate LGP may be formed of a transparent polymer resin such as polycarbonate or polymethyl methacrylate. The two largest surfaces of the light guide plate LGP, which are opposed to each other, are parallel to the display panel DP. The light guide plate LGP guides light provided by the light emitting unit LEU to the display panel DP. The light incident into the light guide plate LGP is transmitted to the display panel DP through the top surface of the light guide plate LGP.

In the one embodiment, the light emitting unit LEU is disposed along a single side of the light guide plate LGP, but is not limited thereto. For example, in another embodiment of the inventive concept, the light emitting units LEU may be arrayed along other sides of the light guide plate LGP. Although the display device includes edge-type light source units in the current embodiment, the display device may include direct-type light source units in another embodiment of the inventive concept. When the light emitting unit LEU is a direct-type light source unit, the light emitting unit LEU is disposed under the display panel DP. When the display device includes a direct-type light source unit, a portion of the light guide plate LGP or the optical sheets OPS may be removed.

The optical sheets OPS are disposed between the light guide plate LGP and the display panel DP. The optical sheets OPS control light emitted from the light emitting unit LEU. The optical sheets OPS include a diffusion sheet DFS, a prism sheet PSM, and a protective sheet PRS, which are sequentially stacked on the light guide plate LGP. The diffusion sheet DFS diffuses the light. The prism sheet PSM collects the light diffused by the diffusion sheet DFS in a direction perpendicular to the display panel DP. Most of the light passing through the prism sheet PSM is perpendicularly incident to the display panel DP. The protective sheet PRS is disposed on the prism sheet PSM. The protective sheet PRS protects the prism sheet PSM from external shock. In one embodiment, the optical sheets OPS include one diffusion sheet as the diffusion sheet DFS, one prism sheet as the prism sheet PSM, and one protective sheet as the protective sheet PRS, but the inventive concept is not limited thereto. At least one of the diffusion sheet DFS, the prism sheet PSM, and the protective sheet PRS may be provided in a plural number to the optical sheets OPS, or at least one of the diffusion sheet DFS, the prism sheet PSM, and the protective sheet PRS may be removed.

The reflective sheet RFS is disposed on the bottom chassis BC under the light guide plate LGP. The reflective sheet RFS reflects light otherwise wasted back to the display panel DP. Thus, the reflective sheet RFS increases the amount of light provided to the display panel DP.

The top chassis TC is disposed over the display panel DP. The top chassis TC supports upper edges of the display panel DP, and may cover side surfaces of the mold frame MF or the bottom chassis BC. The top chassis TC includes a display window WD exposing a display region of the display panel DP.

The bottom chassis BC is disposed under the backlight assembly BA to accommodate components of the backlight assembly BA.

Light emitted from the light emitting unit LEU is provided to the display panel DP through the light guide plate LGP and the optical sheets OPS. The display panel DP transmits or blocks the light to provide an image forward.

FIG. 3 is a cross-sectional view illustrating a light emitting unit according to the inventive concept.

Referring to FIG. 3, the light emitting unit includes at least one light emitting diode LED for emitting light, a light emitting layer LEL disposed on the light emitting diode LED, and a housing HSG to accommodate the light emitting diode LED and the light emitting layer LEL.

The housing HSG has an opening and a space to accommodate the light emitting diode LED and the light emitting layer LEL. That is, the housing HSG includes a bottom portion HSG1 on which the light emitting diode LED may be mounted, and a side portion HSG2 extending upward from the bottom portion HSG1 and connected to the bottom portion HSG1. The housing HSG may be formed of an electrically insulating polymer such as a plastic. For example, the housing HSG may be formed of a material such as polyphthalamide (PPA). When the housing HSG is fabricated, the bottom portion HSG1 and the side portion HSG2 may be integrally formed using a molding method.

The light emitting diode LED emits first light having a peak wavelength corresponding to a blue color. The first light may have a peak wavelength ranging from about 380 nm to about 470 nm. The light emitting diode LED may be mounted on the bottom portion HSG1 of the housing HSG, and is connected to an external power source (not shown) through a wire WR. The wire WR may pass through the housing HSG and connect to an external power source. The external power source applies voltage to drive the light emitting diode LED.

The light emitting layer LEL is disposed on the light emitting diode LED. The light emitting layer LEL includes a polymer resin in which a plurality of quantum dots QD and a plurality of fluorescent particles FL are dispersed. The polymer resin may be formed of an electrically insulating polymer such as a silicon resin, an epoxy resin, and an acrylic resin.

The quantum dots QD are one of nano-materials that may include a core, a shell surrounding the core, and a ligand attached to the shell. According to quantum confinement effect, when light of a wavelength, which is higher in energy than a band gap, is incident to the quantum dots QD the quantum dots QD absorb the light and are excited to emit light of a specific wavelength. The emitted light has a value corresponding to the band gap. In this case, the band gap has a specific value according to the size of the quantum dots QD and spectral characteristics having narrow full width at half maximum are exhibited.

According to the inventive concept, each of the quantum dots QD absorbs light emitted from the light emitting diode LED and emits light corresponding to a band gap thereof. That is, the light emitting diode LED absorbs the first light to emit a second light that has a longer wavelength than that of the first light. Since the second light has a wavelength corresponding to a green color, the second light may have a peak wavelength ranging from about 500 nm to about 560 nm. The quantum dots QD emitting the second light may be formed of at least one of ZnSe, CdSe, and InGaP.

The fluorescent particles FL absorb the first light emitted from the light emitting diode LED and the second light emitted from the quantum dots QD. The fluorescent particles FL are excited to emit a third light that has a longer wavelength than those of the first or second light. Since the third light has a wavelength corresponding to a red color the third light may have a peak wavelength ranging from about 580 nm to about 650 nm.

The fluorescent particles FL emitting the third light may be a nitride-based fluorescent particle. For example, the fluorescent particles FL may include at least one of CaAlSiN₃:Eu and SrAlSiN₃:Eu.

The light emitting unit LEU emits more improved white light than a typical light emitting unit does. This is because the light emitting unit LEU is superior in spectroscopic color reproduction to a light emitting unit including typical fluorescent particles. Particularly, the light emitting unit LEU has a greater color reproduction area in a green region on sRGB coordinates than a light emitting unit including typical fluorescent particles.

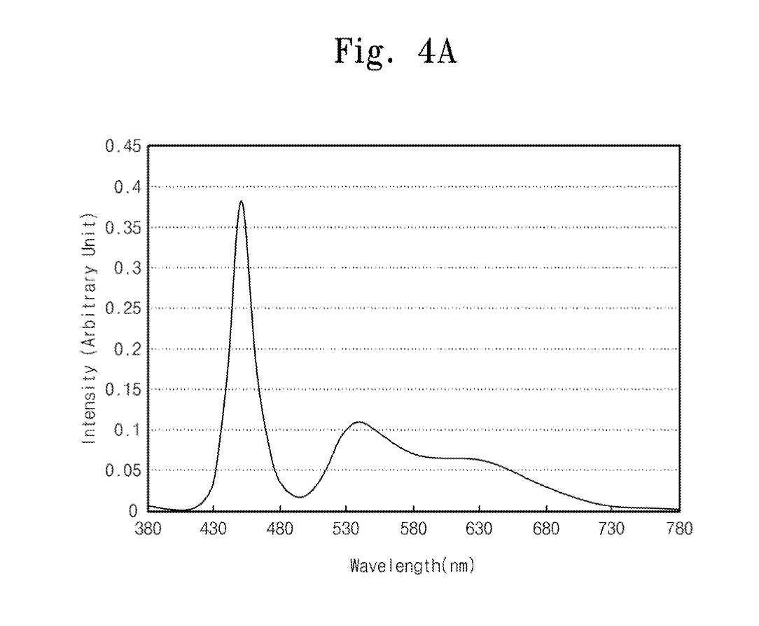

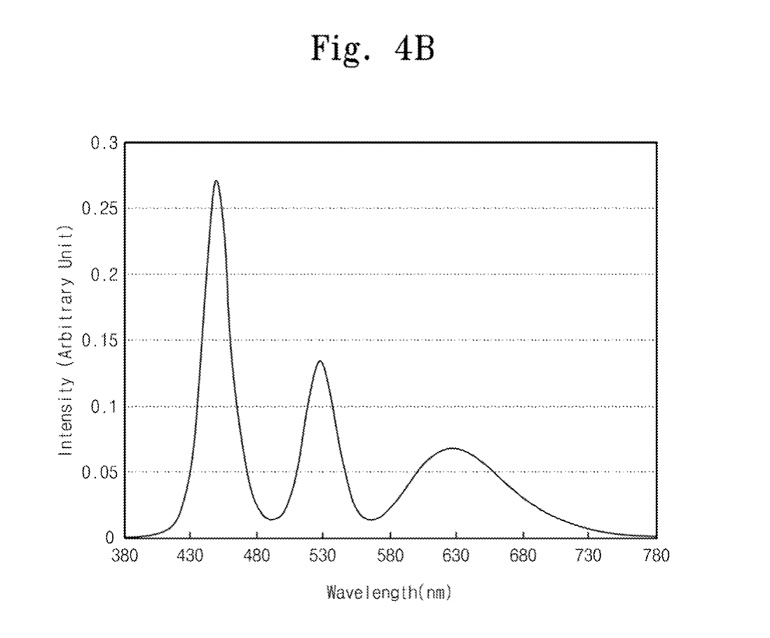

FIG. 4A is a spectral energy distribution graph of a typical light emitting unit including fluorescent particles. FIG. 4B illustrates a spectral energy distribution graph of a light emitting unit according to an embodiment of the inventive concept. In FIGS. 4A and 4B, relative intensities of light according to wavelengths are shown.

The typical light emitting unit of FIG. 4A includes a blue light emitting diode, nitride-based red fluorescent particles, and nitride-based green fluorescent particles. The nitride-based red fluorescent particle is formed of CaAlSiN₃:Eu²⁺, and the nitride-based green fluorescent particle is formed of Si_{6-z}Al_{z}O_{z}N_{8-z} (0<z=3.6). The light emitting unit according to the embodiment of FIG. 4B includes the blue light emitting diode, the nitride-based red fluorescent particles, and green quantum dots.

Referring to FIGS. 4A and 4B, a blue peak, a green peak, and a red peak are sequentially formed as a wavelength increases.

The green and red peaks of FIG. 4B are narrower than those of FIG. 4A in full width at half maximum. In addition, the green and red peaks of FIG. 4B are higher than those of FIG. 4A in intensity. Since the green peak of FIG. 4B has the narrower full width at half maximum and the higher intensity than that of FIG. 4A, a green color reproduction area significantly increases.

Since an overlapping wavelength range between the green and red peaks of FIG. 4A is wide, a green color may be mixed with a red color. Due to the green and red peaks of FIG. 4B being narrower, an overlapping wavelength range between the green and red peaks of FIG. 4B is less than the overlap between the green and red peaks of FIG. 4A. As such, as a separation degree between peaks increases, colors are more clearly separated from each other. As a result, unlike the typical light emitting unit, according to the inventive concept since there is no mixing or interference of the green and red peaks color pureness is improved, and particularly, green color reproduction on the sRGB coordinates are significantly improved.

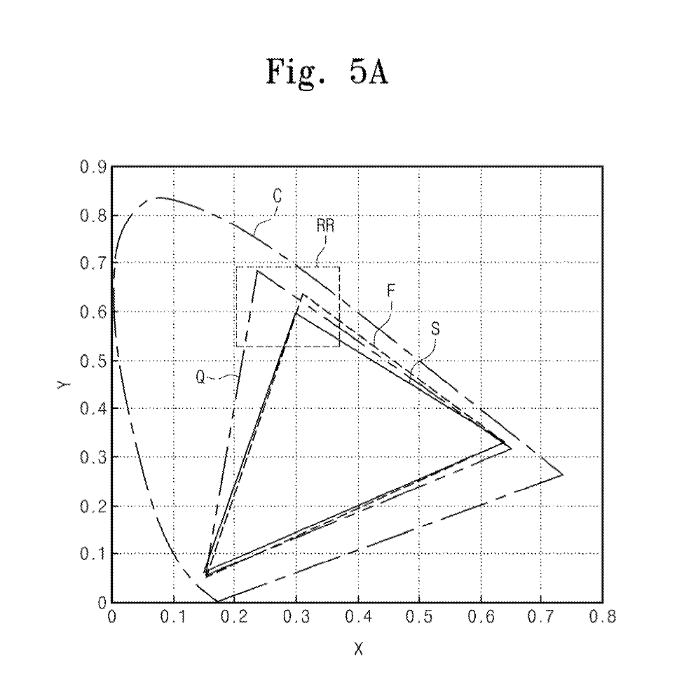

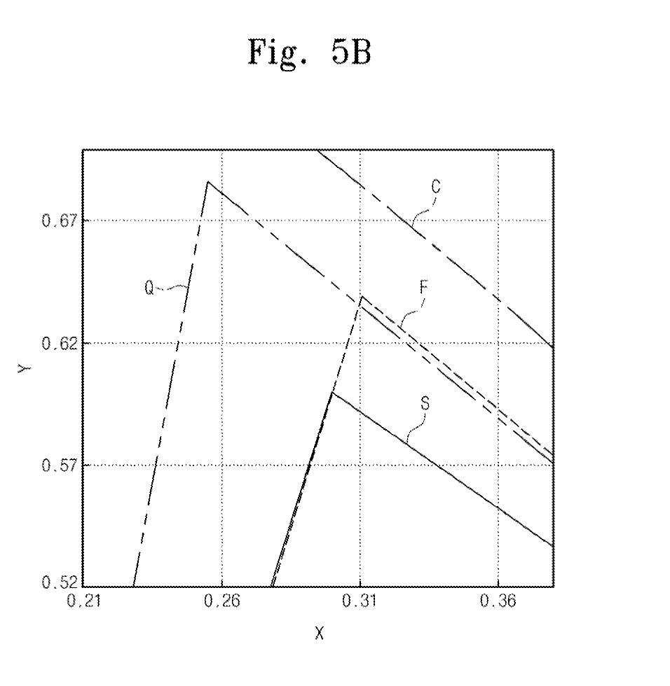

FIG. 5A is a diagram of color coordinates (x, y) illustrating color reproduction regions of a light emitting unit in a CIE 1931 standard colorimetric system according to the inventive concept. FIG. 5B is an enlarged view illustrating a portion RR of a green region of FIG. 5A.

In FIGS. 5A and 5B, a region of color coordinates in the CIE 1931 standard colorimetric system is depicted with line C, and a region of the sRGB color coordinates is depicted with line S. In addition, a color reproduction region of a typical light emitting unit is depicted with line F, and a color reproduction region of the light emitting unit of an embodiment described herein is depicted with line Q.

Table 1 shows x values, y values, and a gamut on the color coordinates of the CIE 1931 standard colorimetric system, and u′ values, v′ values, and a gamut on color coordinates of a CIE 1976 standard colorimetric system, in the color reproduction region of the light emitting unit according to one embodiment.

TABLE 1

| | |
|---|---|
| CIE 1931 | CIE 1976 |

| | x | y | u′ | v′ |
|---|---|---|---|---|
| WHITE | 0.260 | 0.290 | — | — |
| RED | 0.653 | 0.316 | 0.476 | 0.519 |
| GREEN | 0.255 | 0.695 | 0.094 | 0.578 |
| BLUE | 0.153 | 0.055 | 0.183 | 0.147 |

| | | |
|---|---|---|
| GAMUT | 92.7 | 106.9 |

Referring to FIGS. 5A and 5B, and Table 1, the color reproduction area of the light emitting unit according to one embodiment is larger than that of the typical light emitting unit. Particularly, a green color reproduction region thereof is large. Accordingly, the light emitting unit of the embodiment described herein is superior in color reproduction when compared to the typical light emitting diode, thus emitting purer white light.

Since the light emitting unit as described herein has a large green color reproduction region a display device including a color filter layer combined with the light emitting unit can emit brighter light. Particularly, when a green region of the color filter combined with the light emitting unit is decreased, transmissivity of a display panel is increased, thereby improving the brightness of an image. This is because the brightness of an image provided by the display device is most affected by a green color among red, green, and blue colors. Contribution levels of the red, green, and blue colors to the brightness of an image provided by the display device are about 18%, 72%, and 10%, respectively. In this case, the above-described green color reproduction region may be adjusted to correspond to an sRGB green color reproduction region, thereby maintaining the optimum color condition of a typical display device.

To reduce the green color reproduction region to correspond to the sRGB green color reproduction region the thickness of the color filter layer should be decreased or the colors of the color filters should be adjusted. For example, a yellow dye may be added to a green portion of the color filter layer to increase transmissivity in a wavelength band for expressing a yellow color, thereby reducing the green color reproduction region.

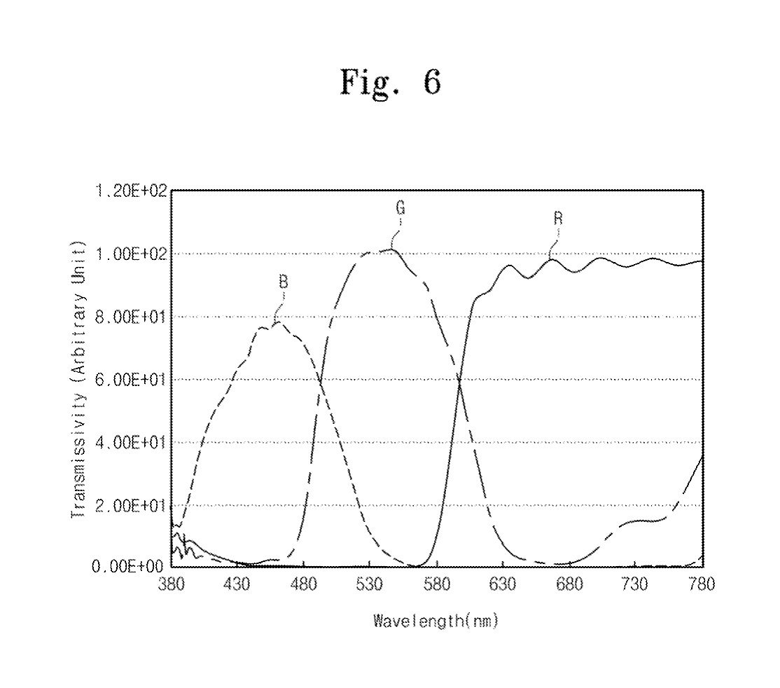

FIG. 6 is a graph illustrating transmissivity of color filters, combined with a light emitting unit according to wavelengths. In FIG. 6, transmissivity of a first color filter expressing a blue color is depicted with line B, transmissivity of a second color filter expressing a green color is depicted with line G, and transmissivity of a third color filter expressing a red color is depicted with line R.

Referring to FIG. 6, a first wavelength band of the blue color corresponding to the first color filter has an upper limit of about 550 nm. Since visible light has a wavelength of about 380 nm or greater, the first wavelength band is equal to or greater than about 380 nm. A second wavelength band of the green color corresponding to the second color filter ranges from about 450 nm to about 655 nm. A third wavelength band of the red color corresponding to the third color filter has a lower limit of about 540 nm. Since visible light has a wavelength of about 780 nm or less, the third wavelength band has an upper limit of about 780 nm. The ranges of the first to third wavelength bands are given by expressing a region corresponding to a transmissivity of about 95%, as a boundary value.

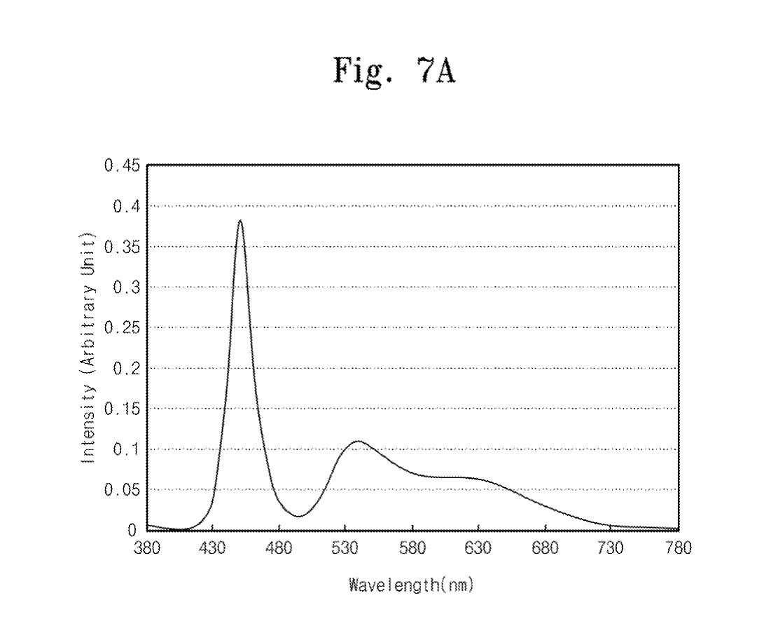

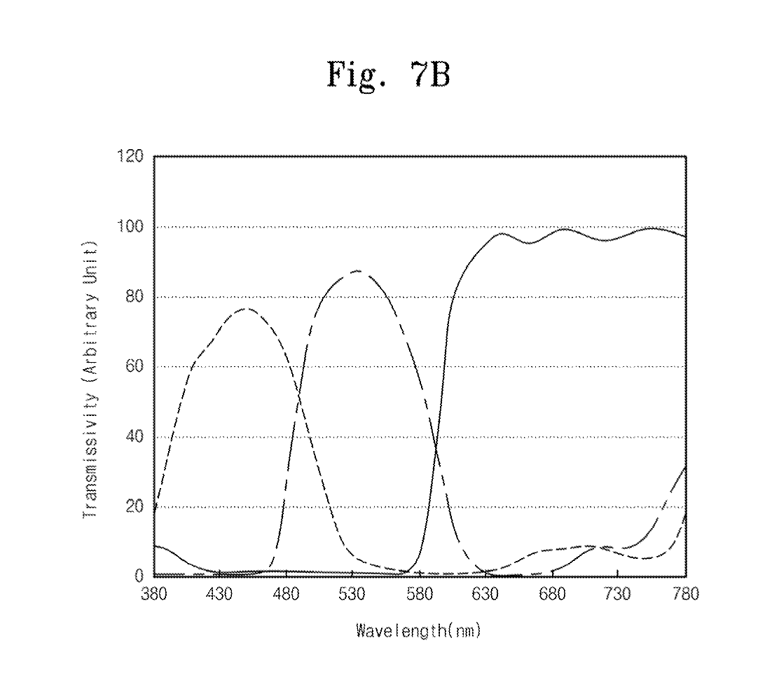

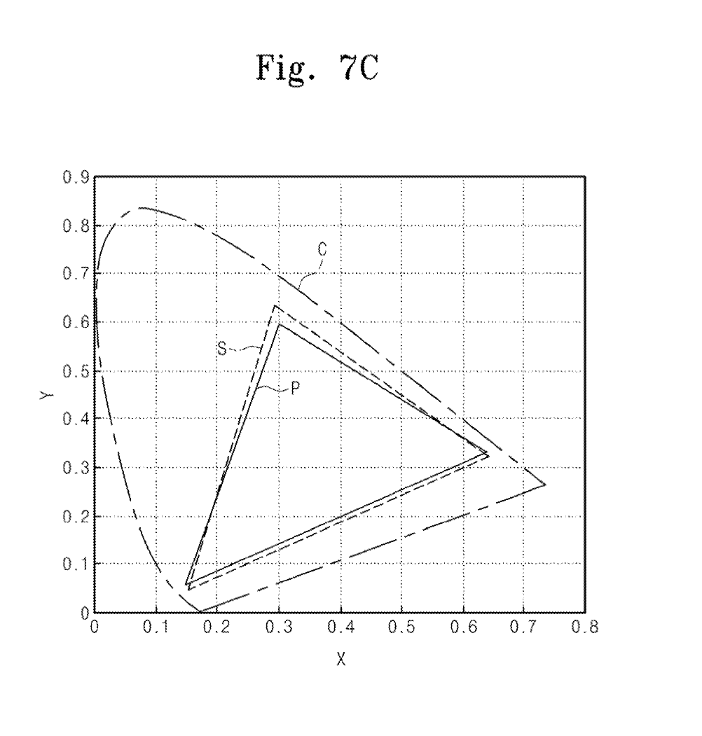

Hereinafter, experimental examples with a typical display device and a display device according to an embodiment of the inventive concept will now be described with reference to FIGS. 7A through 7C, FIGS. 8A through 8C, and FIGS. 9A through 9C.

### Experimental Example

FIGS. 7A through 7C are graphs illustrating a display device including a typical light emitting unit and typical color filters. In detail, FIG. 7A is a spectral energy distribution graph of the typical light emitting unit. FIG. 7B is a graph illustrating transmissivity of the typical color filters according to wavelengths. FIG. 7C is a diagram of color coordinates (x, y) illustrating a color reproduction region of the display device including the typical light emitting unit and the typical color filters in the CIE 1931 standard colorimetric system. In FIG. 7C, the region of the color coordinates of the CIE 1931 standard colorimetric system is depicted with line C, and the region of the sRGB color coordinates is depicted with line S, and the color reproduction region of the display device is depicted with line P.

The typical light emitting unit included a blue light emitting diode, a nitride-based red fluorescent material, and a nitride-based green fluorescent material. The nitride-based red fluorescent material is formed of CaAlSiN₃:Eu²⁺, and the nitride-based green fluorescent material is formed of Si_{6-z}Al_{z}O_{z}N_{8-z} (0<z=3.6).

Table 2 shows x values, y values, and a gamut on the color coordinates of the CIE 1931 standard colorimetric system, and u′ values, v′ values, and a gamut on the color coordinates of the CIE 1976 standard colorimetric system, according to the current experimental example.

TABLE 2

| | |
|---|---|
| CIE 1931 | CIE 1976 |

| | x | y | u′ | v′ |
|---|---|---|---|---|
| WHITE | 0.2900 | 0.3073 | 463 nit- | |
| RED | 0.6320 | 0.3230 | 0.4505 | 0.5180 |
| GREEN | 0.2930 | 0.6372 | 0.1165 | 0.5700 |
| BLUE | 0.1540 | 0.0420 | 0.1927 | 0.1183 |

| | | |
|---|---|---|
| GAMUT | 77.6 | 95.0 |

### Another Experimental Example

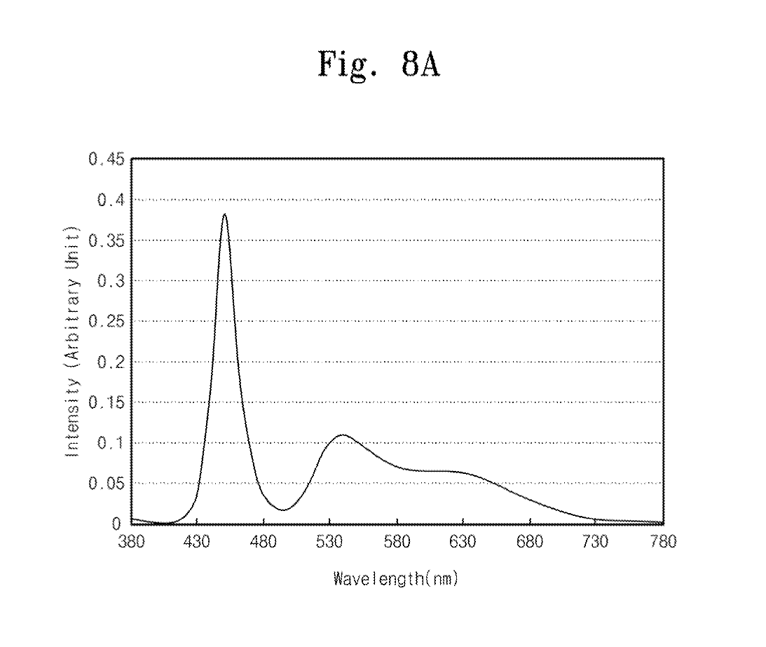

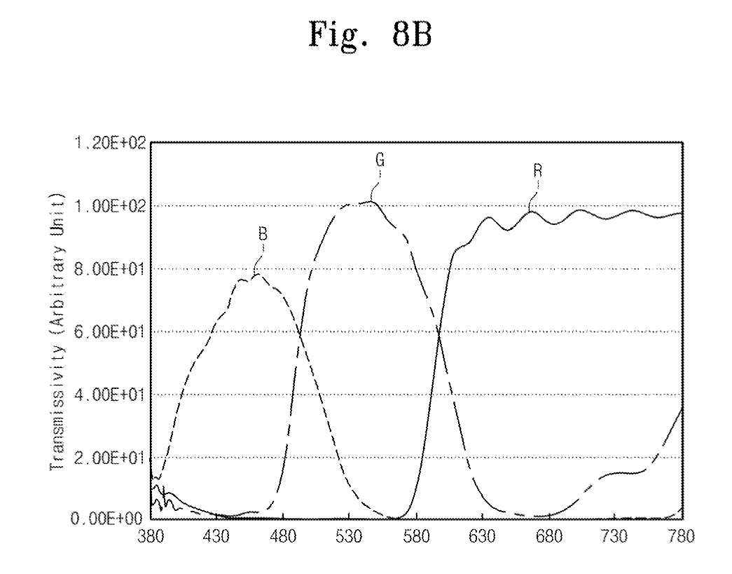

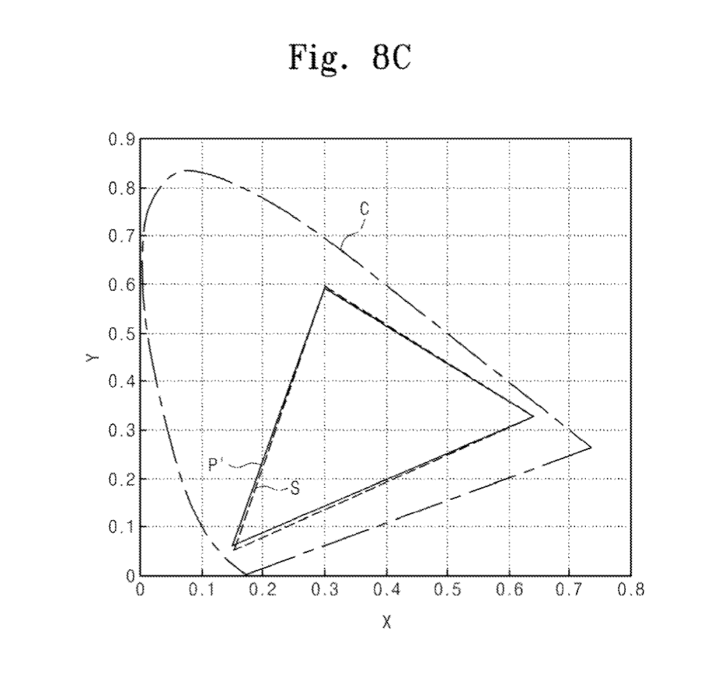

FIGS. 8A through 8C are graphs illustrating a display device including a light emitting unit according to an embodiment of the inventive concept and typical color filters. In detail, FIG. 8A is a spectral energy distribution graph of the light emitting unit. FIG. 8B is a graph illustrating transmissivity of the typical color filters according to wavelengths. FIG. 8C is a diagram of color coordinates (x, y) illustrating a color reproduction region of the display device including the light emitting unit and the typical color filters in the CIE 1931 standard colorimetric system. In FIG. 8C, the region of the color coordinates of the CIE 1931 standard colorimetric system is depicted with line C, and the region of the sRGB color coordinates is depicted with line S, and the color reproduction region of the display device according to the current experimental example is depicted with line P′.

The light emitting unit according to the embodiment of the inventive concept included the blue light emitting diode, the nitride-based red fluorescent material, and the green quantum dots.

Table 3 shows x values, y values, and a gamut on the color coordinates of the CIE 1931 standard colorimetric system, and u′ values, v′ values, and a gamut on the color coordinates of the CIE 1976 standard colorimetric system, according to the current experimental example.

TABLE 3

| | |
|---|---|
| CIE 1931 | CIE 1976 |

| | x | y | u′ | v′ |
|---|---|---|---|---|
| WHITE | 0.2638 | 0.2862 | 509 nit | |
| RED | 0.6405 | 0.3318 | 0.4494 | 0.5238 |
| GREEN | 0.3002 | 0.6035 | 0.1245 | 0.5633 |
| BLUE | 0.1515 | 0.0523 | 0.1823 | 0.1416 |

| | | |
|---|---|---|
| GAMUT | 72.1 | 86.0 |

### Another Experimental Example

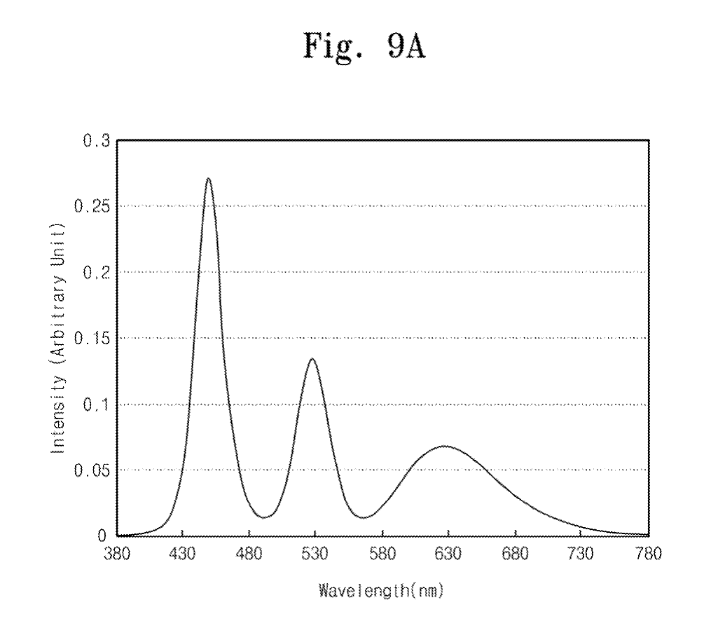

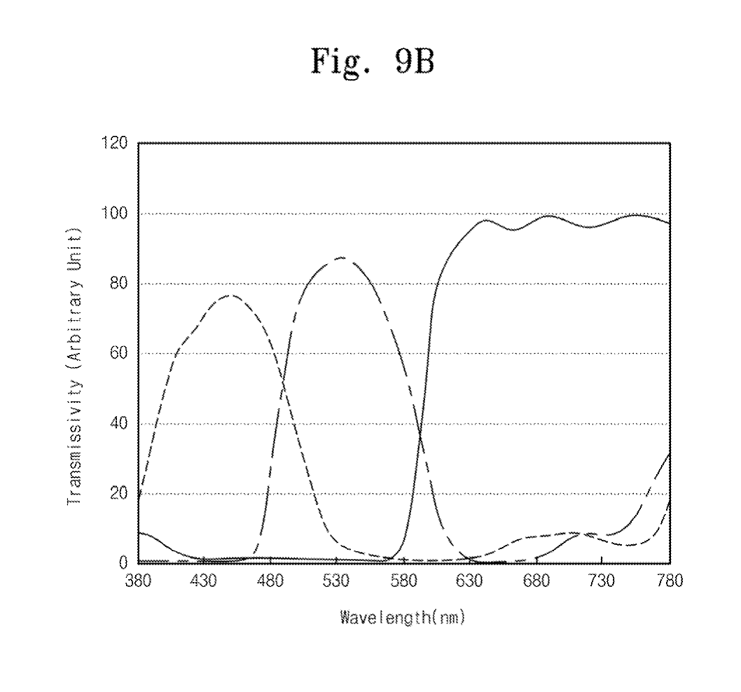

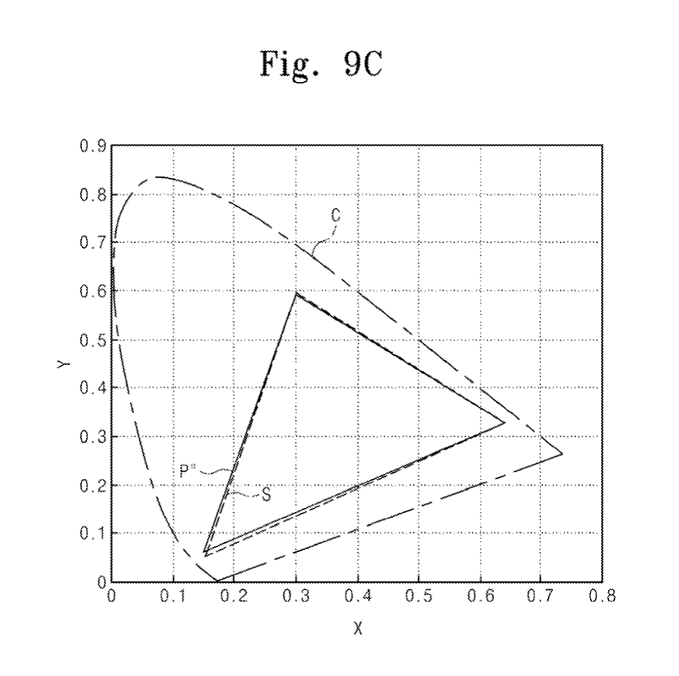

FIGS. 9A through 9C are graphs illustrating a display device including a light emitting unit and color filters according to an embodiment of the inventive concept. In detail, FIG. 9A is a spectral energy distribution graph of the light emitting unit of the embodiment of the inventive concept. FIG. 9B is a graph illustrating transmissivity of the color filters of the embodiment of the inventive concept, according to wavelengths. FIG. 9C is a diagram of color coordinates (x, y) illustrating a color reproduction region of the display device including the light emitting unit and the color filter according to the embodiment of the inventive concept in the CIE 1931 standard colorimetric system. In FIG. 9C, the region of the color coordinates of the CIE 1931 standard colorimetric system is depicted with line C, and the region of the sRGB color coordinates is depicted with line S, and the color reproduction region of the display device according to the embodiment of the inventive concept is depicted with line P″.

The light emitting unit according to the embodiment of the inventive concept included the blue light emitting diode, the nitride-based red fluorescent material, and the green quantum dots.

Table 4 shows x values, y values, and a gamut on the color coordinates of the CIE 1931 standard colorimetric system, and u′ values, v′ values, and a gamut on the color coordinates of the CIE 1976 standard colorimetric system, according to the current experimental example.

TABLE 4

| | |
|---|---|
| CIE 1931 | CIE 1976 |

| | x | y | u′ | V′ |
|---|---|---|---|---|
| WHITE | 0.2745 | 0.2862 | 598 nit | |
| RED | 0.6404 | 0.3314 | 0.4497 | 0.5236 |
| GREEN | 0.30000 | 0.6041 | 0.1244 | 0.5635 |
| BLUE | 0.1500 | 0.0518 | 0.1806 | 0.1404 |

| | | |
|---|---|---|
| GAMUT | 72.3 | 86.0 |

### RESULTS

Since the gamuts in the experimental examples were 77.6, 72.1, and 72.3, there was no remarkable difference therebetween. In addition, since coincidence ratios of the color reproduction regions of the experimental examples to the region of the sRGB color coordinates were 98%, 99%, and 99%, there was no remarkable difference therebetween, and the color coordinates corresponding to the color reproduction regions of the experimental examples substantially satisfied sRGB criteria.

However, when the brightness of the display device according to the experimental example of FIG. 7C was assumed to be 100%, the brightness of the display device according to the experimental example of FIG. 8C was about 110%, and the brightness of the display device according to the experimental example of FIG. 9C was about 127%. Therefore, even when a typical color filter of a display device is coupled to a light emitting unit according to an embodiment of the inventive concept, the brightness of the display device is increased by about 10%. Furthermore, when a light emitting unit according to an embodiment of the inventive concept is coupled to a color filter according to an embodiment of the inventive concept, the brightness of a display device is increased by about 27% when compared to the display device according to the experimental example of FIG. 7C, and is increased by about 17% when compared to the display device according to the experimental example of FIG. 8C.

Thus, according to an embodiment of the inventive concept, when a display device includes light emitting units and color filters, the number of the light emitting units can be decreased, thereby reducing manufacturing costs of the display device.

According to an embodiment of the inventive concept, a light emitting unit has excellent color reproducibility. In addition, according to another embodiment of the inventive concept, when a display device includes light emitting units and color filters, the number of the light emitting units can be decreased, thereby reducing manufacturing costs of the display device.

The above-disclosed subject matter is to be considered illustrative and not restrictive, and the appended claims are intended to cover all such modifications, enhancements, and other embodiments, which fall within the spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A display device comprising:
a display panel displaying an image; and
a light emitting unit providing white light to the display panel,
wherein the light emitting unit includes:
at least one light source emitting a first light; and
a light emitting layer comprising:
a plurality of quantum dots disposed on the light source and absorbing the first light to emit a second light, the second light having a wavelength different from a wavelength of the first light; and
a plurality of fluorescent particles absorbing the first light to emit a third light, the third light having a wavelength different from the wavelengths of the first and second light.

2. The display device of claim 2, wherein the first light is a blue light, the second light is one of a red light and a green light, and the third light is the other of the red light and the green light.

3. The display device of claim 2, wherein the quantum dots comprise at least one of ZnSe, CdSe, and InGaP.

4. The display device of claim 3, wherein the first light has a peak wavelength ranging from about 380 nm to about 470 nm.

5. The display device of claim 2, wherein the second light is green light, and the third light is red light.

6. The display device of claim 5, wherein the fluorescent particles comprise nitride-based fluorescent particles.

7. The display device of claim 6, wherein the nitride-based fluorescent particles comprise at least one of CaAlSiN₃:Eu and SrAlSiN₃:Eu.

8. The display device of claim 7, wherein the second light has a peak wavelength ranging from about 500 nm to about 560 nm, and the third light has a peak wavelength ranging from about 580 nm to about 650 nm.

9. The display device of claim 6, wherein the display panel comprises:
a first substrate;
a second substrate opposed to the first substrate;
an image display layer disposed between the first and second substrates; and
a color filter layer disposed between the first substrate and the image display layer or between the second substrate and the image display layer to express a color.

10. The display device of claim 9, wherein the color filter layer comprises:
a first color filter for transmitting light of a first wavelength band;
a second color filter for transmitting light of a second wavelength band different from the first wavelength band; and
a third color filter for transmitting light of a third wavelength band different from the first and second wavelength bands,
wherein the second wavelength band ranges from about 450 nm to about 655 nm.

11. The display device of claim 10, wherein the first wavelength band ranges from about 380 nm to about 550 nm.

12. The display device of claim 10, wherein the third wavelength band ranges from about 540 nm to about 780 nm.

13. The display device of claim 10, wherein the first substrate comprises a plurality of pixels, and each of the pixels corresponds to one of the first, second, and third filters.

14. The display device of claim 1, wherein the display panel is a liquid crystal display panel, an electrophoretic display panel, an electrowetting display panel, or a microelectromechanical system (MEMS) display panel.

15. A light emitting unit comprising:
a light emitting diode for emitting a first light; and
a light emitting layer,
wherein the light emitting layer includes:
a plurality of quantum dots disposed on the light emitting diode and absorbing the first light to emit a second light, the second light having a wavelength different from a wavelength of the first light; and
a plurality of fluorescent particles absorbing the first light to emit third light, the third light having a wavelength different from the wavelengths of the first and second light.

16. The light emitting unit of claim 15, wherein the first light is a blue light, the second light is one of a red light and a green light, and the third light is the other of the red light and the green light.

17. The light emitting unit of claim 16, wherein the second light is green light, and the third light is red light.

18. The light emitting unit of claim 17, wherein the fluorescent particles comprise nitride-based fluorescent particles.

19. The light emitting unit of claim 18, wherein the fluorescent particles comprise at least one of CaAlSiN₃:Eu and SrAlSiN₃:Eu.

20. The light emitting unit of claim 15, wherein the quantum dots comprise at least one of ZnSe, CdSe, and InGaP.
